(19) United States
(12) Patent Application Publication
(10) Pub. No.: US 2007/0269596 A1
(43) Pub. Date: Nov. 22, 2007

(54) VALVE FAILURE DETECTION

(75) Inventors: Eric J. Shero, Phoenix, AZ (US); Gabor Szogyenyi, Phoenix, AZ (US)

Correspondence Address: KNOBBE, MARTENS, OLSEN & BEAR LLP, 2040 MAIN STREET, FOURTEENTH FLOOR, IRVINE, CA, 92614, US

(73) Assignee: ASM America, Inc., Phoenix, AZ (US)

(21) Appl. No.: 11/751,535

(22) Filed: May 21, 2007

Related U.S. Application Data
(60) Provisional application No. 60/801,821, filed on May 19, 2006.

(51) Int. Cl. C23C 16/00; B05C 11/00

(52) U.S. Cl. 427/248.1; 118/715; 118/708

(57) ABSTRACT

A method and apparatus for determining changes in a supply system, designed to supply repeated pulses of a vapor phase reactant to a reaction chamber is disclosed. One embodiment involves providing the reactant source, and a gas conduit to connect the reactant source to the reaction chamber, a valve positioned in communication with the reactant source such that switching of the valve induces vapor phase reactant pulses from the reactant source to the reaction chamber and a pressure sensor positioned in communication with the reactant source and configured to provide a plurality of pressure measurements over a period of time. A monitoring apparatus is configured to determine if the plurality of pressure measurements exceeds a high pressure limit or a low pressure limit during the period of time

### PRIORITY INFORMATION

This application claims the priority benefit under 35 U.S.C. § 119(e) of Provisional Application 60/801,821, filed May 19, 2006, the entirety of which is hereby incorporated by reference herein.

### BACKGROUND OF THE INVENTION

1. Field of the Invention

The present invention relates to chemical processes and, more particularly, to chemical processes for producing a thin film on a substrate by subjecting the substrate to repeated pulses of gas or vapor-phase reactants.

2. Description of the Related Art

There are several vapor deposition methods for growing thin films on the surface of substrates. These methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Epitaxy (ALE), which is more recently referred to as Atomic Layer Deposition (ALD).

ALE or ALD is a deposition method that is based on the sequential introduction of precursor species (e.g., a first precursor and a second precursor) to a substrate, which is located within a reaction chamber. The growth mechanism relies on the adsorption of one precursor (or fragments thereof) on active sites of the substrate without thermal decomposition. Conditions are such that no more than a monolayer forms in one pulse so that the process is self-terminating or saturative. For example, the first precursor can include ligands that remain on the adsorbed species, which prevents further adsorption. Temperatures are maintained above precursor condensation temperatures and below thermal decomposition temperatures such that the precursor chemisorbs on the substrate(s) largely intact. This initial step of adsorption is typically followed by a first removal (e.g., pumping or purging) stage wherein the excess first precursor and possible reaction byproducts are removed from the reaction chamber. The second precursor is then introduced into the reaction chamber. The second precursor typically reacts with the adsorbed species, thereby producing the desired thin film. This growth terminates once the entire amount of the adsorbed first precursor has been consumed. The excess of second precursor and possible reaction byproducts are then removed by a second removal stage. The cycle can be repeated so as to grow the film to a desired thickness. Cycles can also be more complex. For example, the cycles can include three or more reactant pulses separated by purge and/or pump down steps, and the sequences of pulses can differ.

ALE and ALD methods are described, for example, in Finnish patent publications 52,359 and 57,975 and in U.S. Pat. Nos. 4,058,430 and 4,389,973, which are herein incorporated by reference. Apparatuses suited to implement these methods are disclosed in, for example, U.S. Pat. No. 5,855,680, Finnish Patent No. 100,409, Material Science Report 4(7) (1989), p. 261, and Tyhjiötekniikka (Finnish publication for vacuum techniques), ISBN 951-794-422-5, pp. 253-261, which are incorporated herein by reference. ASM Microchemistry Oy, Espoo, Finland, supplies such equipment for the ALD process under the trade name ALCVD™.

According to conventional techniques, such as those disclosed in FI Patent publication 57,975, the removal stages involve a purging with a protective gas pulse, which forms a diffusion barrier between precursor pulses and also sweeps away the excess precursors and the gaseous reaction products from the substrate. Valves typically control the pulsing of the precursors and the purge gas. The purge gas is typically an inert gas, for example, nitrogen.

In some ALD reactors, some or all of the precursors may be initially stored in a container in a liquid or solid state. Precursors for may ALD processes are solid or liquid under standard conditions due to the nature of the reactions, which are to be conducted above the condensation temperature but below the thermal decomposition temperature. Suitable metal and semiconductor precursors thus include solid halides (e.g., HfCl₂, ZrCl₂, liquid organometallics. Such reactors are disclosed in co-pending U.S. patent application Ser. No. 09/854,707, filed May 14, 2001, and 09/835,931, filed Apr. 16, 2001, which are hereby incorporated herein by reference. Within the container, the precursor is heated to convert the solid or liquid precursor to a gaseous or vapor state. Typically, a carrier gas is used to transport the vaporized precursor to the reactor. The carrier gas is usually an inert gas (e.g., nitrogen), which can be the same gas that is used for the purging stages.

It is possible for parts of the gas supply system (e.g., the various valves and conduits between the precursor container and the reactor) of the ALD reactor to become damaged or worn out. This can result in contamination and CVD-type reactions between the precursors, thereby compromising the ALD process. However, there are currently few satisfactory techniques for determining in real time when the gas supply system has become compromised.

### SUMMARY OF THE INVENTION

Therefore, a need exists for an improved method and apparatus for determining when the valves, conduits and connections in a vapor deposition reactor system are worn out or damaged, preferably before worn out or damaged parts lower the throughput of the reactor. One problem associated with ALD systems such in particular is that ALD systems typically utilize rapid pulses that occur in time periods on the order of seconds and/or milliseconds. These short time periods makes it difficult to detect failures in the ALD system because of the rapidly changing conditions in the gas supply system. Failure in the gas supply system can lead to poor film deposition, uniformity, defects, growth rate, surface roughness, film density and many other properties can be impacted by CVD or incomplete ALD in the ALD reaction chamber, and many wafers can be run before conventional means (e.g., ex situ metrology) discover any problem. Accordingly, it would be desirable to be able to determine when the gas supply system has failed or is starting to fail before such poor films are deposited.

Accordingly, one aspect of the present invention comprises a method for determining changes in a reactant supply system that is designed to supply repeated pulses of a vapor phase reactant to a reaction chamber. The method comprising providing a reactant source and a gas conduit system to connect the reactant source to the reaction chamber. One or more valves can be positioned in the gas conduit system such that switching of the valve induces vapor phase reactant pulses, separated by inert gas, from the reactant source to the reaction chamber. The one or more valves are repeatedly switched valve to induce the repeated vapor phase reactant pulses. The pressure is measured over a period of time during the process at is sampled at a certain frequency. It is determined if the pressure exceeds a high pressure limit or falls below a low pressure limit during the period of time. An alarm signal is generated if the pressure does not exceed the high pressure limit or does not fall below the low pressure limit a certain number of times during the monitoring period.

Another aspect of the present invention is an apparatus for supplying repeated vapor phase reactant pulses to a reaction chamber. The apparatus comprising a reactant source, a gas conduit system that connects the reactant source and the reaction chamber, and a valve positioned in the gas conduit system such that switching of the valve induces vapor phase reactant pulses from the reactant source to the reaction chamber. A pressure sensor is in communication with gas conduit system and is configured to measure pressure over a period of time. A diagnostic and control unit samples is configured to sample the pressure at a certain frequency and to determine if the pressure exceeds a high pressure limit or a low pressure limit during the period of time and to generate an alarm if the pressure does not exceed the high pressure limit or fall below the low pressure limit a set number of times during the period of time.

Another aspect of the present invention is an apparatus for supplying repeated vapor phase reactant pulses to a reaction chamber that comprises a gas conduit system that connects a reactant source to a reaction chamber. One or more valves are positioned in the gas conduit system such that switching of the valve(s) induces reactant pulses from the reactant source to the reaction chamber. A pressure sensor is in communication with gas conduit system. The pressure sensor is configured to measure pressure over a period of time. The apparatus also includes means for determining if the valve has failed by determining if the pressure measurements exceeds a high pressure limit or a low pressure a certain number of limit during the monitoring period.

Another aspect of the present invention comprises a monitoring apparatus for an ALD reactor which includes a pressure sensor and a diagnostic and control unit, and an alarm. The diagnostic and control unit is configured to determine if a plurality of pressure measurements taken by the pressure sensor exceed a high pressure limit or a low pressure limit during the period of time and to activate the alarm if the plurality of pressure measurements does not exceed the high pressure limit or the low pressure limit a set number of times during the period of time.

Another aspect of the present invention comprises a method for determining a valve malfunction within an ALD system. The method comprises measuring a plurality of pressure measurements over a period of time; determining if the plurality of pressure measurements exceeds a high pressure limit or a low pressure limit during the period of time and generating a control signal or if the plurality of pressure measurements does not exceed the high pressure limit or the low pressure limit a set number of times during the period of time.

It should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

It should also be noted that all of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

In the following, the invention will be described in greater detail with the help of exemplifying embodiments illustrated in the appended drawings, in which like reference numbers are employed for similar features in different embodiments and, in which

FIG. 1 is a schematic illustration of a system for supplying repeated vapor phase reactant pulses to a reaction chamber according to an embodiment of the present invention.

FIG. 2 is a pressure-time graph illustrating pressure fluctuations in a gas system of a cyclic ALD process in the system of FIG. 1 in a first condition

FIG. 3 is a pressure-time graph illustrating pressure fluctuations in a gas system of a cyclic ALD process in the system of FIG. 1 in a second condition.

FIG. 4 is a flow chart illustrating a method of operating a monitoring apparatus of the system of FIG. 1.

### DETAILED DESCRIPTION OF THE PREFERRED EMBODIMENT

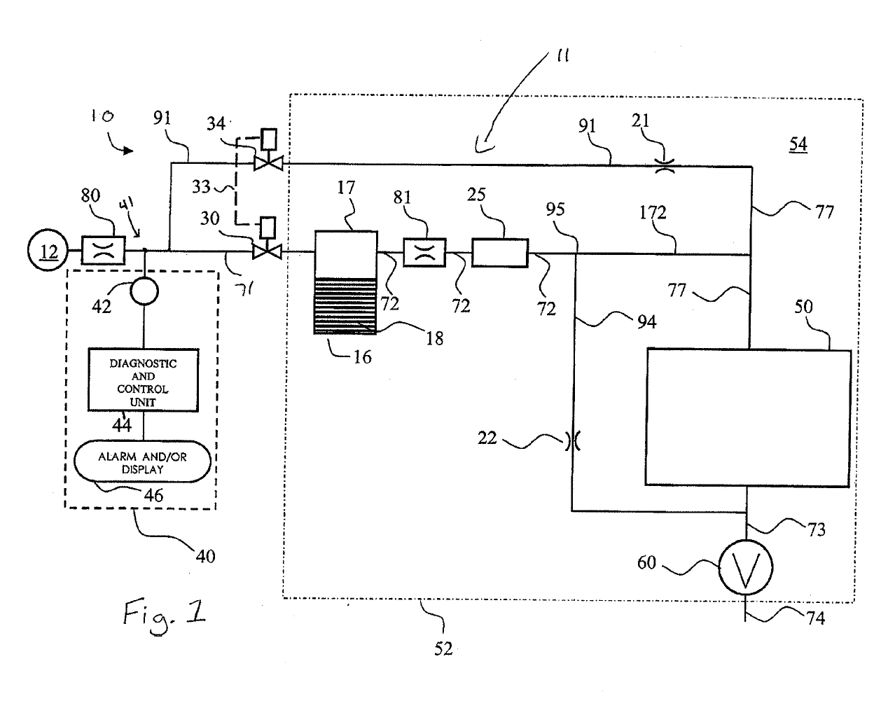

FIG. 1 is a schematic illustration of an ALD system 10 having certain features and advantages according to the present invention. The ALD system 10 includes a monitoring apparatus 40, which can be configured as explained below to measure pressure in the ALD system to determine if there has been a valve failure or degradation/failure of another component of the ALD system (e.g., a line blockage with chemical). The monitoring apparatus 40 is described in the context of an ALD system 10 because the monitoring apparatus has particular utility in this context. Specifically, ALD reactors often utilize high speed pulsing, which makes it difficult to determine if there has been valve failure and/or degradation in the ALD system. For example, monitoring a mass flow controller (MFC) to determine whether a valve has failed by comparing actual flow rates to expected flow rates will often not be effective due for fast pulsing ALD valves. This is further compromised by the data sampling rate and the number of key analog and digital inputs that need to be monitored every cycle by the control system for the ALD system. However, certain features, aspects, and advantages of the pulse monitoring apparatus 40 described herein may find utility with other types of industrial chemical processes, such as, but not limited to, chemical vapor deposition.

In addition, while the preferred embodiment illustrates monitoring in the context of an inert gas flow that is shunted or alternated between a deposition chamber and vent, and even more particularly, to an embodiment employing inert gas valving, the skilled artisan will appreciate that the monitoring system described herein is more generally applicable. Similarly, while illustrated in the context of solid and liquid precursor sources, the skilled artisan will appreciate that the monitoring system is also applicable to precursors stored in a liquid (bubblers) or gaseous form.

As shown in FIG. 1, the illustrated ALD system 10 comprises an inactive or “purge” gas source 12, a reactant source 16, and a reaction chamber 50 in which a substrate (not shown) can be positioned. In a more typical ALD system, at least two sources of two mutually reactive reactants are provided and the substrate is subjected to alternating and repeated pulses of both reactants. However, for illustrating the present embodiment, only one reactant source 16 is indicated. The inactive gas source 12 provides an inactive gas to facilitate transport of the reactant to the reaction chamber 50 and to purge the reaction chamber 50. In the present context, “inactive gas” refers to a gas that is admitted into the reaction chamber and which does not react with reactant or with the substrates during at least one pulse. In some embodiments, a single gas may be inactive in one pulse and made active (e.g., by plasma activation) for other pulses or stages of a process. Examples of suitable inactive gases include, but are not limited to, nitrogen gas and noble gases (e.g., helium, argon). As is well known in the art of ALD processing, purging of the reaction chamber involves feeding an inactive gas into the reaction chamber 50 between two sequential and alternating vapor-phase pulses of the reactants from the reactant source 16 and a second reactant source, not shown. The purging is carried out in order to reduce the concentration of the residues of the reactant of the previous vapor-phase pulse before the next pulse of the other reactant is introduced into the reaction chamber 50. In other arrangements, the reaction chamber 50 can be pumped down between reactant pulses, with or without purging.

In the illustrated arrangement, the same inactive gas, from a single source, is used as carrier gas and as purge gas. In modified embodiments, two separate sources can be used, one for carrier gas and one for purge gas. In such embodiments, when the reactant is not being delivered to the reaction chamber 50, the carrier gas can be diverted to an exhaust instead of the reaction chamber 50. As will be explained below, the purging gas in the illustrated embodiment can also be used for providing a gas barrier against the flow of reactant residues into the reaction chamber 50 during the purging of the reaction chamber 50.

The illustrated reactant source 16 includes a container 17 or similar vessel, which is capable of containing solid and/or liquid reactant material 18 and in which the reactant material 18 can be vaporized. The container 17 can be provided with an inlet nozzle (not shown), which is connected to a carrier gas supply conduit 71 for introduction of a carrier gas into the container 17 from the inactive gas source 12. The container 17 is also provided with an outlet nozzle (not shown), which is connected to the reactant conduit 72, which interconnects the reactant source 16 with the reaction chamber 50 through an inlet conduit 77. The reactant source 16 can be equipped with a heater (not shown) for vaporizing the reactant material 18. Alternatively, feeding heated carrier gas into the reactant source 16 can carry out heating. One embodiment of a reactant source container is described in co-pending U.S. patent application Ser. No. 09/854,706, filed May 14, 2001, the entire contents of which are hereby incorporated by reference herein.

The inactive gas source 12 in the illustrated embodiment is also connected to the reaction chamber 50 through a purge conduit 91, which is connected to an inlet conduit 77 of the reaction chamber 50. As mentioned above, in a modified embodiment, a second inactive gas source can be connected to the reaction chamber 50 through a separate purge conduit. In such an embodiment, the shown inactive gas source 12 can be connected to an exhaust through an exhaust line, thus shunting a continuous (and thus stable) inactive gas stream between the reactant source 16 and exhaust (or vent).

An outlet conduit 73 can be connected to the reaction chamber 50 for removing unreacted vapor-phase reactants and reaction by-products from the reaction chamber 50. The outlet conduit 73 is preferably connected to the evacuation pump 60. The exhaust conduit 74 is connected to the outlet of the vacuum pump 60.

The illustrated ALD system 10 can include a bypass conduit 94, with a first end connected to the reactant conduit 72 at a point 95 between the reactant gas source 16 and the inlet conduit 77 and a second end connected to the outlet conduit 73. In a modified arrangement, the bypass conduit 94 can be connected directly to the evacuation pump 60 or to a separate evacuation pump. In yet another embodiment, the bypass conduit 94 can be eliminated.

In the illustrated arrangement, the conduits described above are preferably formed from inert material, such as, for example, an inert metal (e.g., stainless steel), Teflon™, ceramic material, or glass.

With continued reference to FIG. 1, a mass flow controller 80 and a reactant valve 30 are positioned along the carrier gas supply conduit 71. The purging conduit 91 can also include a shut-off valve 34, which in this embodiment will be referred to as the purging valve 34. As will be explained below, the reactant valve 30 and the purging valve 34 can be used to alternately direct the carrier gas to the reactant source 16 and to the purging conduit 91. For this purpose, the reactant valve 30 and the purging valve 34 can be connected by a connection 33, such that the valves 30 and 34 are oppositely switched simultaneously. Consequently, when the reactant valve 30 is opened, the purging valve 34 is closed, and when the reactant valve 30 is closed, the purging valve 34 is opened. The connection 33 can be operated mechanically, pneumatically, or via a control loop. In modified embodiments, the reactant and purging valves 30, 34 can be replaced with a single valve placed in either the carrier gas supply conduit 71 or the purging conduit 91. In another embodiment, a three way valve can be placed between the carrier gas supply conduit 71 and the purging conduit 91. In another embodiment, valve 34 is left open and valve 30 is switched to alternately direct some of the carrier gas through the source container 17 or all of it to the reactor 50. One skilled in the art would realize that multiple valves could be used (for example, isolation valves on vessel inlet/outlet, N2 isolation (12 area), etc.).

In the illustrated embodiment, flow restrictors 21, 22 can be positioned in the purging conduit 91 and the bypass conduit 94, respectively. The flow restrictors 21 and 22 reduce the cross-sectional area of the conduits 91 and 94 and direct the reactant from the reactant source 16 to the reaction chamber 50, rather than into the purging and bypass conduits 91 and 94, during a reactant pulse. In modified embodiments, flow restrictors 21, 22 can be eliminated or additional flow restrictors can be added to the system 10. Flow restrictions could be variable in order to adjust split of flow between 91 path and 95 path if both are open.

The dashed line 52 indicates a hot zone 54 within the ALD system 10. Preferably, the temperature within the hot zone 54 is kept at or above the vaporization temperature of the reactant material 18 and preferably below the thermal decomposition temperature of the reactants. Depending upon the reactant, the temperature within the hot zone 54 is typically in the range of about 10 to 500 degrees Celsius and, often in the range of about 15 to 300 degrees Celsius. The pressure in the reaction chamber 50 and in the conduits 71, 72, 77, 91, 94 that communicate with the reaction chamber 50 can be atmospheric, but more typically the pressure is below atmospheric in the range of about 10 to 800 mbar absolute.

Preferably, the reactant and purging valves 30, 34 are positioned outside the hot zone 54. That is, within the hot zone 54 there are no valves that can completely close the conduits. The flow restrictors 21 and 22, however, can be positioned within the hot zone 54, as shown. Such an arrangement reduces the degradation of the valves 20, 24 that would occur within the hot zone 54.

According to the illustrated arrangement, the bypass conduit 94 is not closed by a valve during the pulsing of reactants from the reactant source 16. As such, during a reactant pulse, a small fraction of the flow of reactant from the reactant source 16 flows into the bypass conduit 94 and into the evacuation pump 60. As such, the flow restrictor 22 in bypass conduit 94 is preferably sized such that the flow through the bypass conduit 94 is less than about one fifth of that in the reactant conduit 72. More preferably, the flow restrictors 22 are sized such that flow in the bypass conduit 94 is less than about 15%, and most preferably less than about 10% of the flow in the reactant conduit 72. The restrictors 21, 81 is preferably similarly sized to give a difference in resistance to purge and pulse paths, respectively.

With continued reference to FIG. 1, the illustrated ALD system 10 preferably also includes a purifier/filter 25 for removing impurities, such as, for example, fine solid particles and liquid droplets, from the reactant source 16. The separation of such impurities can be based on the size of the particles or molecules, the chemical character, and/or the electrostatic charge of the impurities. In one embodiment, the purifier 25 comprises a filter or a molecular sieve. In other embodiments, the purifier 25 comprises an electrostatic filter or a chemical purifier comprising functional groups capable of reacting with specific chemical compounds (e.g., water in precursor vapors). Preferably, the purifier 25 is positioned along the reactant conduit 72 between the reactant source 16 and the reaction chamber 50. More preferably, the purifier 25 is positioned along the reactant conduit 72 at a point between the reactant source 16 and the connection 95 with the bypass conduit 94. In this manner, the vapor flows in one direction only over the purifier 25 and the gas phase barrier is formed between the purifier 25 and the reaction chamber 50.

The ALD system 10 of the illustrated embodiment can be operated as follows. The mass flow controller 80 is typically set at a substantially constant set point (e.g., 1000 sccm). In one embodiment, for a reactant pulse, the reactant valve 30 is opened while the purging valve 34 is closed. Inactive carrier gas from the mass flow controller 80 flows through the reactant source 16 wherein the solid or liquid reactant 18 is vaporized such that a vapor exists in the container 17 above the solid or liquid reactant. Thus, reactant 18 from the reactant source 16 is carried in vapor form by the carrier gas through the reactant conduit 72 and the purifier 25 through the inlet conduit 77 into the reaction chamber 50. There can also be small flow of inactive carrier gas and reactant vapors into bypass conduit 94.

During a purging pulse, the mass flow controller 80 can stay at substantially the same set point while the reactant valve 30 is closed and the purging valve 34 is opened. Purging gas, therefore, flows first through the purging conduit 91 and then through the reaction chamber inlet conduit 77 into the reaction chamber 50. Moreover, a gas phase barrier is formed in a portion 172 of the reactant conduit 72 between the point 95 and the inlet conduit 77 as some of the purging gas flows into the reactant conduit 72 from the purging conduit 91 via the inlet conduit 77. This purging gas also flows into the bypass conduit 94 and into the evacuation pump 60. As such, the flow direction of gas is reversed in the portion 172 of the reactant conduit 72 located between the inlet conduit 77 and the bypass conduit 94.

The reactant residues withdrawn via the bypass conduit 94 can be recycled. In such a modified arrangement, the bypass conduit 94 is connected to a condensation vessel maintained at a lower pressure and/or temperature than the hot zone 54 in order to provide condensation of vaporized reactant residues.

The system 10 described above can be extended to include a second reactant source. In such an arrangement, a second reactant source can be positioned within a conduit system in a manner similar to that described above. Such an arrangement is described in co-pending U.S. patent application Ser. No. 09/835,931, filed Apr. 16, 2001, which is hereby incorporated by reference herein. Of course, the ALD system 10 can also be expanded to more than two reactant sources in light of the disclosure herein. Further more, one, two or all the reactant sources can be stored in gaseous form rather than solid or liquid form.

As mentioned above, one problem associated with ALD systems such as the ALD system 10 described above and other chemical processing systems that utilize rapid pulses (e.g., time periods of seconds and milliseconds) of reactants is that it is difficult to detect failures in the ALD system 10 because of the rapidly changing conditions in the gas supply system 11 (i.e., the various valves 30, 34 and/or conduits 91, 71, 72, 77 etc.) and due to asynchronicity between process step times and control system I/O monitoring. For example if a pulse is 10 ms wide and occurs every 500 ms and I/O monitory system is monitoring pressure every 50 ms the control system will have to check many times before it coincides with pulse condition. Accordingly, if a valve (e.g., valves 30, 34) or other component of the gas supply system 11 fails during a purging and/or reactant pulse, the mass flow controller 80 may only experience a small deviation from set point due to the short disturbance (pulse or purge) times. If only a single valve (is used to direct flow to the reactant source 16 or to the purge line 91 and the single valve fails, very little or no decrease in mass flow may be observed due to the parallel flow paths between the purge line 91 and reactant gas supply line 71. In another example, if the valves 30, 34 are open simultaneously and a portion of MFC 80 flow is directed through vessel and the valve 30 fails, the observed flow at the MFC 80 may remain unchanged by the pressure 42 will change. This situation can occur whether flow is shunted from the reactant source to the chamber or directly to a vent. The valves 30, 34 can fail through a variety of mechanisms, such as, for example, precursor build up due to condensation or decomposition, physical degradation of the valves, and/or pneumatic system failures. The lines 91, 71, 72, etc. can also clog similarly. Failure of the valves can lead to poor deposition uniformity in the reaction chamber 50. Accordingly, it would be desirable to be able to determine when a valve has failed or is starting to fail examining the substrates on which deposition proceeds.

As shown in FIG. 1, the illustrated system 10 includes the pulse monitoring apparatus 40, which can be used to determine if a valve (e.g., valves 30, 34) and/or other component of the gas supply system 11 becomes damaged or fails during the course of a plurality of reactant pulses. In this way, any change in the gas supply system 11 will be detected quickly, so that prompt action can be taken without production losses due to poor process performance. In the illustrated embodiment, the pulse monitoring apparatus 40 comprises a pressure sensor 42, which is preferably in communication with the carrier gas supply conduit 71 at a monitoring position 41, which is preferably upstream of the reactant source 16. However, the sensor 42 and monitoring position 41 can be positioned at other locations (e.g., downstream of the reactant valve 30 or in the purge line 91 in modified embodiments, the illustrated position has an advantage in that the sensor 42 is not exposed to the reactant material 18.

The diagnostic and control unit 44 is preferably operatively connected to an alarm and/or display device 46, which can comprise a display unit for displaying information gathered by the diagnostic and control unit 44. In one embodiment, the alarm and/or display device 46 can generate audio or visual indicia that indicates that a failure has occurred (e.g., a warning light, alarm signal, etc.). In another embodiment, the alarm and/or display device 46 can generate audio or visual indicia when the system 10 is operating normally and/or change or eliminate an audio or visual indicia when a failure has occurred as determined by the diagnostic and control unit 44. In certain embodiments, a failure may not actually have occurred; rather, an event indicating a “failure” criteria has been met. In this manner, a technician or operator can shut down the system 10 and/or take other corrective actions before an actual failure occurs. In this manner, corrective action can be taken before a failure occurs and the process is compromised.

The diagnostic control unit 44 generally comprises a general purpose computer or workstation having a general purpose processor and the memory for storing a computer program that can be configured for performing the steps and functions described below. Part of the memory may be used for storing measurement data collected by the diagnostic and control unit 44. In the alternative, the unit can comprise a hard-wired feedback control circuit, a dedicated processor, or any other control device that can be constructed for performing the steps and functions described below.

The pressure sensor 42 can be configured to measure the pressure within the carrier gas conduit 71 at multiple times and/or continuously during a time period via the control system. The diagnostic control unit 44, in turn, monitors or reads the pressure measurements taken by the pressure sensor 42 at a certain frequency that is typically dictated by the control system 40 resolution or characteristics. The rate at which the pressure measurements are taken will be referred to herein as the sampling rate or I/O sampling rate. In certain embodiments, the sampling rate is greater than the pulsing rate, which refers to the number of pulses during a time period. In other embodiments, the sampling rate can be less than or equal to the pulsing rate.

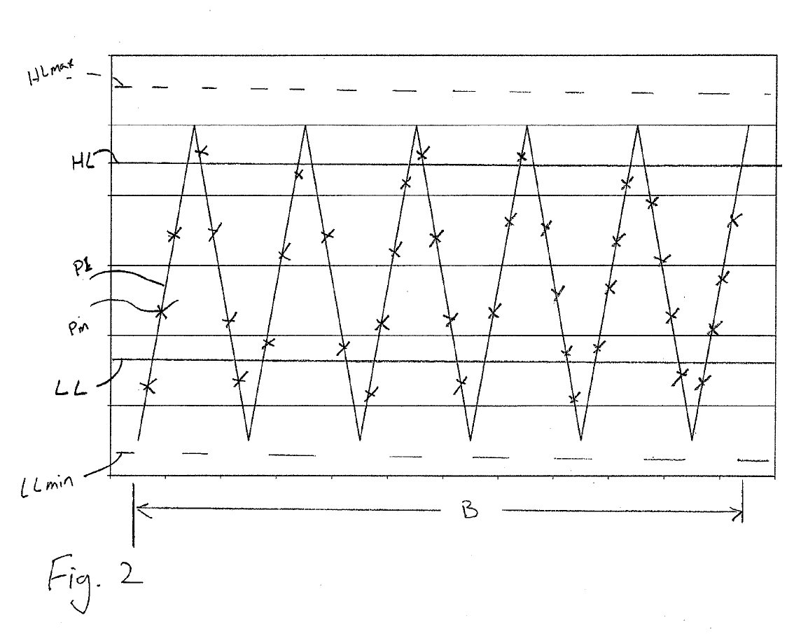

FIG. 2 illustrates an embodiment in which the sampling rate is greater than the pulsing rate. As shown, during normal operation, the pressure P1 upstream of the valves 30, 34 fluctuates from a value above a high pressure limit HL to a value below a low pressure limit LL. The pressure fluctuation is caused by the valves 30, 34, which alternately direct all or a portion of the inactive gas to the reactant gas line 71 and the purge gas line 91. In general, the pressure becomes high when the inactive gas is directed through the purge gas line 91 because of the higher resistance in this gas path as compared when the inactive gas is directed through the reactant gas line 71 or portions through 91 and 71.

As shown, sampling can occur during a time period B at the sampling rate. During this period B, a plurality of pressure measurements Pm are taken by the monitoring apparatus 40, as indicated by the symbol X. During the time period B, the pressure measurements Pm will indicate pressure values that are below the low pressure limit LL and above the high pressure limit HL and many values in-between. The number of times during a period B that the monitoring apparatus 40 will have a pressure measurement Pm exceeding the bounds of these limits will depend upon the pulsing rate of the system 10 and the sampling rate of the apparatus 40.

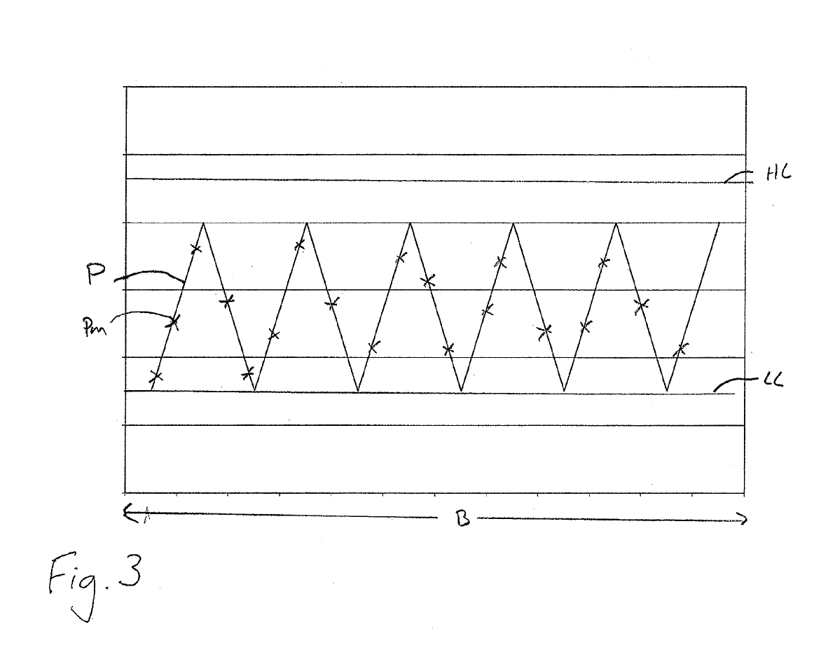

FIG. 3 illustrates a situation in which there has been a failure or degradation in the gas supply system 11 (e.g., a failure of one or more of the valves 30, 34). As illustrated, in such a situation, the pressure P at the measuring point 41 can fail to exceed the high pressure limit HL and/or fail to fall below the low pressure limit LL. Although not illustrated, it is also possible for the pressure P to exceed the high pressure limit HL and/or to fall below the low pressure limit LL but to do so less often or for smaller durations as compared to normal or acceptable operating conditions. In this situation, as shown in FIG. 3, during the time period B, the pressure measurements X sampled by the monitoring apparatus 40 will not measure a pressure Pm above the high pressure limit HL and/or below the low pressure limit.

Accordingly, in one embodiment, the monitoring apparatus 40 can be configured to sample the pressure at the measurement point 41 over the time period B. If the monitoring apparatus 40 measures a statistically predetermined minimum number of pressure values (e.g., one) above the high pressure limit HL and/or measures a predetermined minimum number of pressure values (e.g., one) below the low pressure limit LL during the time period B, the apparatus 40 can be configured to indicate that there has not been a failure in the system 10. Conversely, if the monitoring apparatus 40 does not measure the predetermined minimum number of pressure values above the high pressure limit HL and/or does not measure the predetermined minimum number of pressure values below the low pressure limit LL during the time period B, the apparatus 40 can be configured to generate a signal indicating that there may be a failure in the system 10. In response to the signal, the diagnostic and control unit 44 can provide instructions to the alarm and/or display unit 46 to generate visual and/or audio indicia indicating that a failure or abnormal condition has occurred. In a modified embodiment, the apparatus 40 can be configured such that during the period the monitoring apparatus must measure a pressure value above the high pressure limit HL and/or below the low pressure level LL a certain number of times before generating a signal indicating a normal and/or failure condition.

The high and low pressure limits HL, LL, the time period B, and the number of times the pressure lies above and/or below the limits during the time period needed to generate a signal will generally vary upon the specific reactor system 10, the reactant used, process times, recipes used during the chemical process and ultimately, the acceptable statistical confidence limits the user is willing to accept. Based upon these factors, the high and low limits HL, LL etc. can be calculated and/or determined through empirical testing and arbitrary selection of acceptable variations from a normal or expected value. These monitoring variables can also be adjusted during the initial set up and/or maintenance of the system 10 to minimize false alarms.

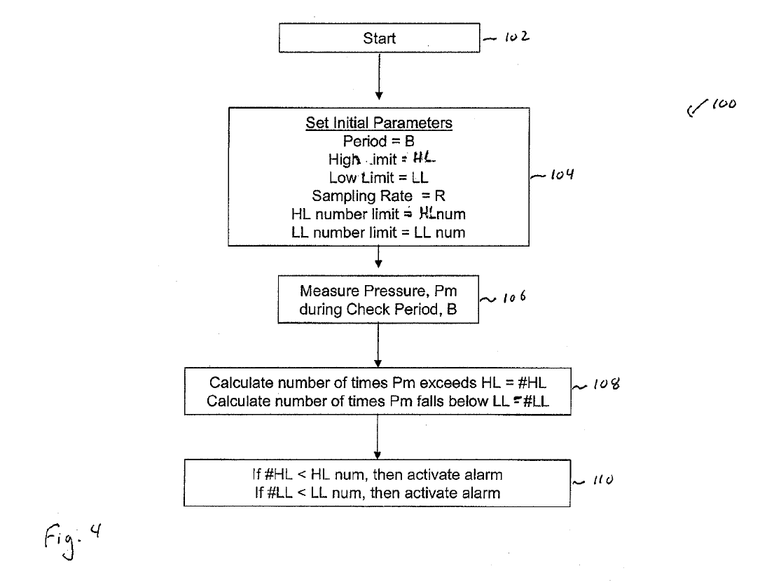

FIG. 4 is a flow chart that graphically illustrates an example control routine 100 that that can be used by the apparatus 40 during operation to determine if there has been a failure in the gas system 11. As shown, the routine 100 starts with a start step 102 in which the apparatus 40 begins operation. The routine 100 then moves to step 104 in which the initial parameters are set. In this embodiment, the initial parameters include the time period B during which the pressure measurements Pm are taken. The time period B is preferably long enough to include multiple pulsing steps. In one embodiment, the period is between about 20 and about 600 seconds and in another embodiment between about 100 and 140 seconds. The initial parameters also include the high pressure limit HL and the low pressure limit LL. The high and low pressure limits HL, LL will be a function of the resistance of the gas system 11 and, in particular, the reactant carrier gas line 71 and the purge gas line 91 during normal operations, respectively. In one embodiment, the high and low pressure limits HL, LL are about 5% to about 15% higher or lower than the peak and minimum pressures observed during normal operations. The sampling rate R equals the number of times during the time period B that the pressure monitoring apparatus 40 measures pressure. The HL number limit (HL num) can be set by the operator and/or manufacturer of the diagnostic system 40 and equals the number of times the measured pressure Pm should exceed the high pressure limit HL during the time period B during normal operating conditions. In a similar manner, the LL number limit (LL num) can be set by the operator and/or manufacture of the diagnostic system 40 and equals the number of times the measured pressure Pm should fall below the low pressure limit LL during the period B during normal operating conditions. In one embodiment, the LL/HL number limits equals 1 and the sampling rate is about 200 ms.

In step 106, the routine 100 measures the pressure during the check period B. The routine 100 then moves to step 108 where the apparatus 40 determines the number of times the measured pressure Pm exceeds the high pressure limit (#HL) and the number of times the measured pressure Pm falls below the low pressure limit (#LL).

In step 110, the apparatus 40 determines if the number of times measured pressure Pm exceeds the high pressure limit (#HL) is less than the HL number limit (HL num). If it is, then the routine 100 (embodied in a computer) instructs the apparatus to activate the alarm 46. In one embodiment, the HL number limit (HL num) equals 1 so that the alarm 46 is only activated if during the time period B the measured pressure does not exceed the high pressure limit HL. In a similar manner, apparatus 40 determines if the number of times measured pressure Pm falls below the low pressure limit (#LL) is less than the LL number limit (LL num). If it is, then the routine 100 instructs the apparatus 40 to activate the alarm 46. In one embodiment, the LL number limit (LL num) equals 1 so that the alarm 46 is only activated if during the time period B the measured pressure does not fall below the low pressure limit LL. In one embodiment, the alarm is generated the number of times measured pressure Pm exceeds the high pressure limit (#HL) is less than the HL number limit (HL num) and the number of times the measured pressure Pm falls below the low pressure limit (#LL) is less than the LL number limit (LL num). In another embodiment, the alarm is generated the number of times measured pressure Pm exceeds the high pressure limit (#HL) is less than the HL number limit (HL num) or the number of times the measured pressure Pm falls below the low pressure limit (#LL) is less than the LL number limit (LL num). It should also be appreciated that the LL num number limit and the HH number LL number can be the same or different values.

Although the embodiments have been described in the context of ALD, with liquid and/or solid phase reactants, it will be understood that the invention is also applicable outside the context of ALD and is also applicable to gaseous reactant sources. In case of a gaseous reactant source, a carrier gas might not be needed.

It should also be appreciated that in modified embodiments, the monitoring apparatus 40 described above can be extended a chemical system in which the gas flow is alternately directed to a source chemical container and directly to a vent (e.g., rather than to the reaction chamber) or is not alternately directed to separate flow paths. In the later case, the pressure in the system will also characteristically change as a valve open and closes. Accordingly, the techniques described above for monitoring the pressure with respect to the high and low pressure limits HL, LL can also be used to determine when there has been a valve failure. Furthermore, the source chemical container could store gaseous reactant and still characteristic pressure fluctuations would be expected as the valves direct carrier or purge gas in difference directions or on and off.

With reference back to FIGS. 2 and 3, in another modified embodiment, the pressure sensor 40 can be configured to measure pressure continuously or substantially continuously. In such an embodiment, the diagnostic and control unit 40 can be configured to generate an alarm or control signal if the pressure measured by the pressure sensor 40 exceeds the high pressure limit HL or falls below the low pressure limit LL during the period of time B. In a modified embodiment, diagnostic and control unit 40 can be configured to generate the alarm or control signal if the pressure exceeds the high pressure limit HL or falls below the low pressure limit LL during the period of time a set number of times. In yet another embodiment, the amount of time that the measured pressure exceeds the high pressure limit HL or falls below the low pressure limit LL during the time period can be calculated by integration or other methods. The amount of time above or below the high and low pressure limits HL, LL can be used in such embodiments as a trigger point for generating the alarm.

As shown in FIG. 2, the diagnostic and control unit 40 can also be provided with a maximum high pressure limit HLmax and a minimum low pressure limit LLmin. As with the high pressure limit HL and low pressure limit LL, the diagnostic control unit 40 can be configured to generate alarm if the pressure exceeds or falls below these limits or if the pressure exceeds or falls bellows these limits more than a predetermined amount of times.

It should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Moreover, although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. For example, it is contemplated that various combination or subcombinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above, but should be determined only by a fair reading of the claims that follow.

We claim:

1. A method for determining changes in a reactant supply system that is designed to supply repeated pulses of a vapor phase reactant to a reaction chamber, the method comprising:
providing a reactant source;
providing a gas conduit system to connect the reactant source to the reaction chamber;
providing one or more valves positioned in the gas conduit system such that switching of the one or more valves valve induces vapor phase reactant pulses from the reactant source to the reaction chamber;
repeatedly switching the valve(s) to induce the repeated vapor phase reactant pulses;
measuring pressure over a period of time;
determining if the pressure exceeds a high pressure limit or falls below a low pressure limit a certain number of times during the period of time; and
generating a control signal if the pressure does not exceed the high pressure limit or does not fall below the low pressure limit a set number of times during the period of time.

2. The method as in claim 1, wherein measuring pressure over a period of time comprises sampling a plurality of pressure measurements over the period of time at a frequency dictated by a control system of the reactant supply system.

3. The method as in claim 2, wherein determining if the pressure exceeds a high pressure limit or falls below a low pressure limit during the period of time comprises determining if the plurality of pressure measurements exceeds the high pressure limit or falls below a low pressure limit during the period of time.

4. The method as in claim 3, wherein generating a control signal if the pressure does not exceed the high pressure limit or does not fall below the low pressure limit a set number of times during the period of time comprises generating the control signal if the plurality of pressure measurements does not exceed the high pressure limit or does not fall below the low pressure limit a set number of times during the period of time.

5. The method as in claim 1, wherein providing a reactant source comprises providing a liquid or solid phase reactant under standard conditions.

6. The method as in claim 5, further comprising providing a source of carrier gas that is connected to the reactant source through a carrier gas conduit and measuring pressure upstream of the reactant source.

7. The method as in claim 1, further comprising switching the valve to alternately direct gas in the gas conduit system between paths of different resistances.

8. The method as in claim 1, further comprising switching the valve to alternately direct gas in the gas conduit system through the reactant source and to a vent.

9. The method as in claim 1, further comprising switching the valve to alternately direct gas in the gas conduit system through the reactant source and through a reaction chamber.

10. The method as in claim 1, wherein atomic layer deposition is conducted in the reaction chamber.

11. The method as in claim 1, wherein the set number of times equals 1.

12. The method as in claim 1, wherein the set number of times is greater than 1.

13. The method as in claim 1, wherein the control signal includes instructions to generate an alarm.

14. The method as in claim 1, wherein the control signal is generated if a control if the pressure does not exceed the high pressure limit and does not fall below the low pressure limit a set number of times during the period of time.

15. An apparatus for supplying repeated vapor phase reactant pulses to a reaction chamber, the apparatus comprising:
a reactant source;
a gas conduit system that connects the reactant source and the reaction chamber;
a valve positioned in the gas conduit system such that switching of the valve induces vapor phase reactant pulses from the reactant source to the reaction chamber;
a pressure sensor that is in communication with gas conduit system and is configured to measure pressure over a period of time; and
a diagnostic and control unit that is configured to determine if the pressure exceeds a high pressure limit or a low pressure limit during the period of time and to generate an alarm if the pressure does not exceed the high pressure limit or fall below the low pressure limit a set number of times during the period of time.

16. The apparatus as in claim 15, wherein the reactant source comprises a liquid or solid phase reactant under room temperature and atmospheric pressure.

17. The apparatus as in claim 15, comprising a source of carrier gas that is connected to the reactant source through a carrier gas conduit.

18. The apparatus as in claim 17, wherein the valve is positioned in the carrier gas conduit upstream of the reactant source such that switching the valve induces carrier gas pulses from the carrier gas source to the reactant source.

19. The apparatus as in claim 15, wherein the set number of times equals 1.

20. The apparatus as in claim 15, wherein the set number of times is greater than 1.

21. The apparatus as in claim 15, wherein the pressure sensor is configured to provide a plurality of pressure measurements over the period of time and the diagnostic and control unit is configured to sample the pressure measurements at an I/O sampling rate and to determine if the plurality of pressure measurements exceeds the high pressure limit or the low pressure limit during the period of time and to generate an alarm if the plurality of pressure measurements does not exceed the high pressure limit or fall below the low pressure limit a set number of times during the period of time.

22. An apparatus for supplying repeated vapor phase reactant pulses to a reaction chamber, the apparatus comprising:
a gas conduit system that connects a reactant source to a reaction chamber;
a valve positioned in the gas conduit system such that switching of the valve induces reactant pulses from the reactant source to the reaction chamber;
a pressure sensor that is in communication with gas conduit system, the pressure sensor configured to measure pressure over a period of time; and
means for determining if the valve has failed by determining the pressure measurements exceeds a high pressure limit or a low pressure limit during the period of time.

23. A monitoring apparatus for an ALD reactor, the apparatus including a pressure sensor, a diagnostic and control unit, and an alarm, wherein the diagnostic and control unit is configured to determine if a plurality of pressure measurements taken by the pressure sensor exceeds a high pressure limit or a low pressure limit during the period of time and to activate the alarm if the plurality of pressure measurements does not exceed the high pressure limit or the low pressure limit a set number of times during the period of time.

24. A method for determining a valve malfunction within an ALD system, the method comprising:
measuring a plurality of pressure measurements over a period of time;
determining if the plurality of pressure measurements exceeds a high pressure limit or a low pressure limit during the period of time; and
generating a control signal if the plurality of pressure measurements does not exceed the high pressure limit or the low pressure limit a set number of times during the period of time.

25. The method as in claim 24, wherein the set number of times equals 1.

26. The method as in claim 24, wherein the set number of times is greater than 1.

27. The method as in claim 24, wherein the control signal includes instructions to generate an alarm.
